(19) United States
(12) Patent Application Publication
(10) Pub. No.: US 2010/0188828 A1
(43) Pub. Date: Jul. 29, 2010

(54) PRINTED CIRCUIT BOARD UNIT AND ELECTRONIC APPARATUS

(75) Inventor: Kazuaki TAKAO, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/751,595

(22) Filed: Mar. 31, 2010

Related U.S. Application Data
(63) Continuation of application No. PCT/JP2007/069222, filed on Oct. 1, 2007.

(51) Int. Cl. H05K 5/00; H05K 7/00

(52) U.S. Cl. 361/759; 361/748

(57) ABSTRACT

A printed circuit board unit includes a printed wiring board. A socket is mounted on the surface of the printed wiring board. A fixation member is mounted on the surface of the printed wiring board at a position spaced from the socket. A screw bore is defined in the fixation member for receiving insertion of a screw. An engagement member is configured to move in the horizontal direction along the surface of the printed wiring board between a reference position and a withdrawing position. The engagement member is set at the reference position so that a predetermined space is defined between the engagement member and the fixation member. The engagement member withdraws from the reference position to the withdrawing position so as to get out of the predetermined space. An elastic member is configured to exhibit an elastic force urging the engagement member toward the reference position.

### CROSS-REFERENCE TO RELATED APPLICATION

This application is a continuing application, filed under 35 U.S.C. §111(a), of International Application PCT/JP2007/069222, filed on Oct. 1, 2007, the contents of which are incorporated herein by reference.

### FIELD

The present invention relates to a printed circuit board unit on which an expansion card such as a PCI-Express Mini Card is mounted.

### BACKGROUND

An expansion card such as a PCI-Express Mini Card is incorporated in a notebook personal computer. The expansion card is assembled in a motherboard. The motherboard includes a printed wiring board. A socket and a fixation member are mounted on the printed wiring board. The fixation member is spaced from the socket at a predetermined distance. One end of the expansion card is held on the socket. The other end of the expansion card is held on the fixation member. In this manner, the expansion card is electrically connected to the printed wiring board.

The fixation member includes a base immobilized on the printed wiring board. The expansion card is received on the base. A claw member is coupled to the base. The claw member is configured to move between a reference position and a withdrawing position. When the claw member is positioned at the reference position, the claw member enters a space right on the expansion card. When the claw member is positioned at the withdrawing position, the claw member withdraws from the space. The claw member at the reference position serves to hold the expansion card on the base. An elastic member is coupled to the base. The elastic member is configured to exhibit an elastic force urging the claw member toward the reference position. The expansion card is removably mounted on the printed wiring board with the assistance of the claw member.
Publication 1: Japanese Patent No. 3306831
Publication 2: Japanese Patent Application Laid-open No. 2002-280766

The socket and the fixation member are sometimes fixed on the printed wiring board at positions shifted from the designed positions so that the relative position between the socket and the fixation member deviates from the designed one. If the interval between the socket and the fixation member is larger than a predetermined interval, the claw member cannot sufficiently enter the space right on the expansion card. As a result, even when a small impact is applied to the motherboard, the expansion card easily separates from the printed wiring board. Accordingly, what is required is means for reliably fixing the expansion card to the printed wiring board.

### SUMMARY

According to an aspect of the invention, a printed circuit board unit includes: a printed wiring board; a socket mounted on the surface of the printed wiring board; a fixation member mounted on the surface of the printed wiring board at a position spaced from the socket by a predetermined distance; a screw bore defined in the fixation member, the screw bore receiving insertion of a screw in a perpendicular direction perpendicular to the surface of the printed wiring board; an engagement member configured to move in the horizontal direction along the surface of the printed wiring board between a reference position and a withdrawing position, the engagement member set at the reference position so that a predetermined space is defined between the engagement member and the fixation member, the engagement member withdrawing from the reference position to the withdrawing position so as to get out of the predetermined space; and an elastic member configured to exhibit an elastic force urging the engagement member toward the reference position.

According to another aspect of the invention, a printed circuit board unit includes: a printed wiring board; a socket mounted on the surface of the printed wiring board, the socket supporting one end of a module substrate; a fixation member mounted on the surface of the printed wiring board at a position spaced from the socket, the fixation member supporting the other end of the module substrate; a screw bore formed in the fixation member, the screw bore receiving insertion of a screw configured to fix the module substrate to the fixation member; and a support member formed in the fixation member, the support member configured to move between a first position at which the support member supports the other end of the module substrate and a second position at which the support member gets distanced from the other end of the module substrate, the support member being urged toward the socket by an elastic member.

The object and advantages of the embodiments will be realized and attained by means of the elements and combinations particularly pointed out in the appended claims. It is to be understood that both the foregoing general description and the following detailed description are exemplary and explanatory and are not restrictive of the embodiments, as claimed.

### BRIEF DESCRIPTION OF THE DRAWINGS

FIG. 1 is a perspective view schematically depicting a notebook personal computer as a specific example of an electronic apparatus according to the present invention;

FIG. 2 is a perspective view schematically depicting a printed circuit board unit according to an embodiment of the present invention;

FIG. 3 is an enlarged partial plan view schematically depicting a fixation mechanism;

FIG. 4 is an enlarged partial sectional view taken along the line 4-4 in

FIG. 3;

FIG. 5 is an enlarged partial plan view schematically depicting the fixation mechanism;

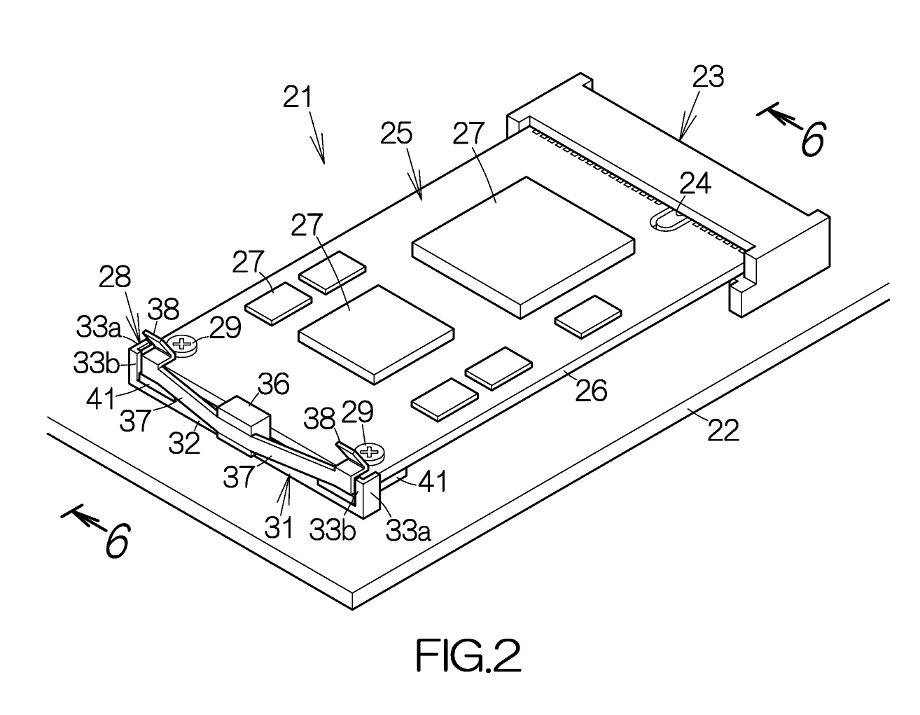

FIG. 6 is an enlarged partial sectional view taken along the line 6-6 in FIG. 2;

FIG. 7 is a perspective view schematically depicting a module substrate having one end inserted into a socket;

FIG. 8 is an enlarged partial sectional view schematically depicting the socket having an inner wall surface supporting the end of the module substrate;

FIG. 9 is an enlarged partial sectional view schematically depicting the module substrate to be set on the fixation mechanism;

FIG. 10 is an enlarged partial sectional view schematically depicting the module substrate to be set on the fixation mechanism; and

FIG. 11 is an enlarged partial sectional view schematically depicting the module substrate to be set on the fixation mechanism.

### DESCRIPTION OF EMBODIMENT

Description will be made below on an embodiment of the present invention with reference to the attached drawings.

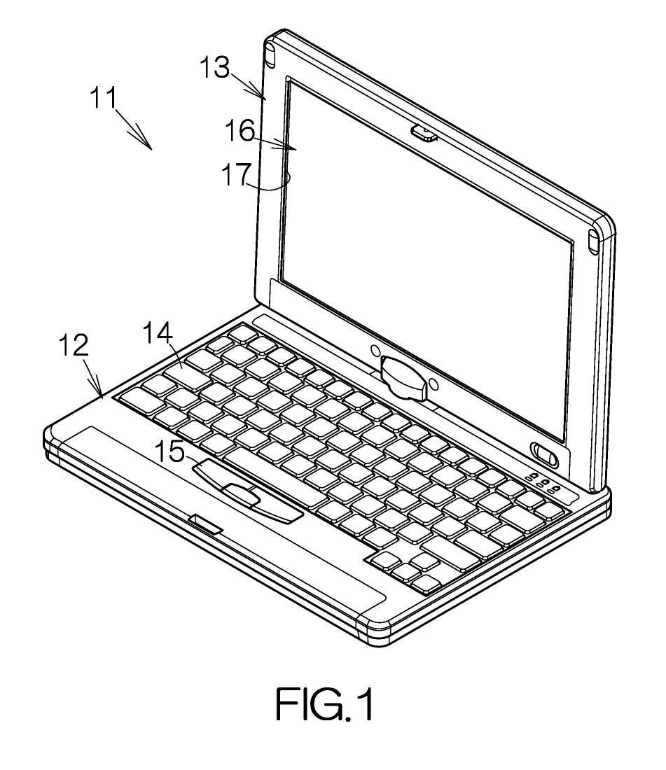

FIG. 1 schematically depicts a notebook personal computer 11 as a specific example of an electronic apparatus according to the present invention. The notebook personal computer 11 includes a thin or flat main enclosure 12 and a flat display enclosure 13. The flat display enclosure 13 is coupled to the flat main enclosure 12 for relative swinging or pivotal movement. Input devices such as a keyboard 14 and input pads 15 are embedded in the surface of the flat main enclosure 12. Users are allowed to manipulate the keyboard 14 and the input pads 15 to input commands and data.

A printed circuit board unit, namely a motherboard, is enclosed in the flat main enclosure 12, for example. The motherboard will be described later in detail. A large-scale integrated circuit (LSI) chip package, a main memory, and the like, are mounted on the motherboard. The LSI chip package is configured to execute various kinds of processing based on a software program and data temporarily held in the main memory, for example. The software program and the data may be stored in a large capacity storage, such as a hard disk drive, HDD, likewise enclosed in the flat main enclosure 12.

A liquid crystal display (LCD) panel module 16 is incorporated in the flat display enclosure 13, for example. The screen of the LCD panel module 16 gets exposed in a window opening 17 defined in the flat display enclosure 13. Text and graphics appear on the screen. Users can see the ongoing operation of the notebook personal computer 11 based on the appearing text and graphics. The flat display enclosure 13 can be superposed on the flat main enclosure 12 through the pivotal movement relative to the flat main enclosure 12.

FIG. 2 schematically depicts a motherboard 21 according to an embodiment of the present invention. The motherboard 21 includes a printed wiring board 22. A resin substrate is employed for the printed wiring board 22. A socket 23 is rigidly mounted on the surface of the printed wiring board 22. A slot 24 is defined in the socket 23. The slot 24 extends in the horizontal direction along the surface of the printed wiring board 22. One end or a first end of an expansion card 25 such as a PCI-Express Mini Card is inserted in the slot 24. The first end of the expansion card 25 is in this manner supported on the socket 23.

The expansion card 25 can be any one of a wireless local area network (LAN) card, a memory card, and the like. The expansion card 25 includes a module substrate 26 and electronic components 27, such as LSI chips, mounted on the upper surface of the module substrate 26. The module substrate 26 has a rectangular contour. Electrically-conductive terminals are arranged along the outer periphery of the module substrate 26 at one of the short sides, namely a first end of the module substrate 26, as described later. The electrically-conductive terminals are connected to electrically-conductive terminals inside the socket 23, respectively. The expansion card 25 is in this manner electrically connected to the printed wiring board 22. The function of the notebook personal computer 11 is expanded.

A fixation mechanism 28 is rigidly mounted on the surface of the printed wiring board 22 at a position spaced from the socket 23 at a predetermined distance. The fixation mechanism 28 has one end facing to the slot 24 of the socket 23. The other end or a second end of the expansion card 25 is fixed to the fixation mechanism 28. A pair of screws 29, 29 is utilized to fix the expansion card 25, for example. The screws 29 are screwed into the fixation mechanism 28. The rotation axes of the screws 29 are set in the perpendicular direction perpendicular to the surface of the printed wiring board 22. The screws 29 serve to reliably immobilize the expansion card 25 on the printed wiring board 22. The expansion card 25 is reliably prevented from falling off the printed wiring board 22.

Referring also to FIG. 3, the fixation mechanism 28 includes a fixation member, namely a base 31, rigidly mounted on the surface of the printed wiring board 22. The base 31 defines a base body 32 extending along the other of the short sides, namely a second end of the module substrate 26. The module substrate 26 is received on the base body 32. The base body 32 extends in parallel with the aforementioned end of the socket 23. The base body 32 is made of a resin material, for example.

A pair of wall members 33a, 33a is defined in the base body 32. The wall members 33a, 33a stand upright from the surface of the base body 32. The wall members 33a extend along the outer periphery of the module substrate 26 at the long sides of the module substrate 26, respectively. The wall members 33a, 33a thus faces to each other across the module substrate 26 interposed therebetween. Likewise, a pair of auxiliary wall members 33b, 33b is defined in the base body 32. The auxiliary wall members 33b, 33b stand upright from the surface of the base body 32. The auxiliary wall members 33b extend along the outer periphery of the module substrate 26 at the short side of the module substrate 26. The auxiliary wall members 33b thus faces to the socket 23. The wall members 33a are connected to the auxiliary wall members 33b at the corners of the module substrate 26, respectively. The wall members 33a and the auxiliary wall members 33b are made of a resin material. The wall members 33a and the auxiliary wall members 33b are formed integral with the base body 32. A predetermined space 34 in the shape of a rectangular parallelepiped is defined inside the wall members 33a and the auxiliary wall members 33b. The module substrate 26 is set within the space 34.

The base 31 includes a block piece 36 defined in the outer end of the base body 32. The block piece 36 is located between the wall members 33a, 33a. The block piece 36 is equally spaced from the wall members 33a, 33a. A pair of elastic members 37, 37 is attached to the block piece 36. The elastic member 37 is a leaf spring in the perpendicular attitude perpendicular to the surface of the module substrate 26. The elastic members 37 may be parts of a single leaf spring. The elastic members 37 extend from the block piece 36 along the outer periphery of the module substrate 26 at the short side of the module substrate 26. The elastic members 37 respectively get closer to the outer periphery of the module substrate 26 as the positions get farther from the block piece 36.

An engagement member 38 is defined in the tip or free end of the individual elastic member 37. The engagement members 38 engage with the second end of the module substrate 26. The aforementioned elastic members 37 exhibit an elastic force for urging the engagement members 38 toward reference positions where the engagement members 38 get into a space right on the module substrate 26, respectively. In other words, the elastic members 37 serve to urge the engagement members 38 toward the socket 23, respectively. As a result, the second end of the module substrate 26 is held between the engagement members 38 taking the reference positions and the base 31. Here, a leaf spring is bent to provide the elastic members 37 and the engagement members 38.

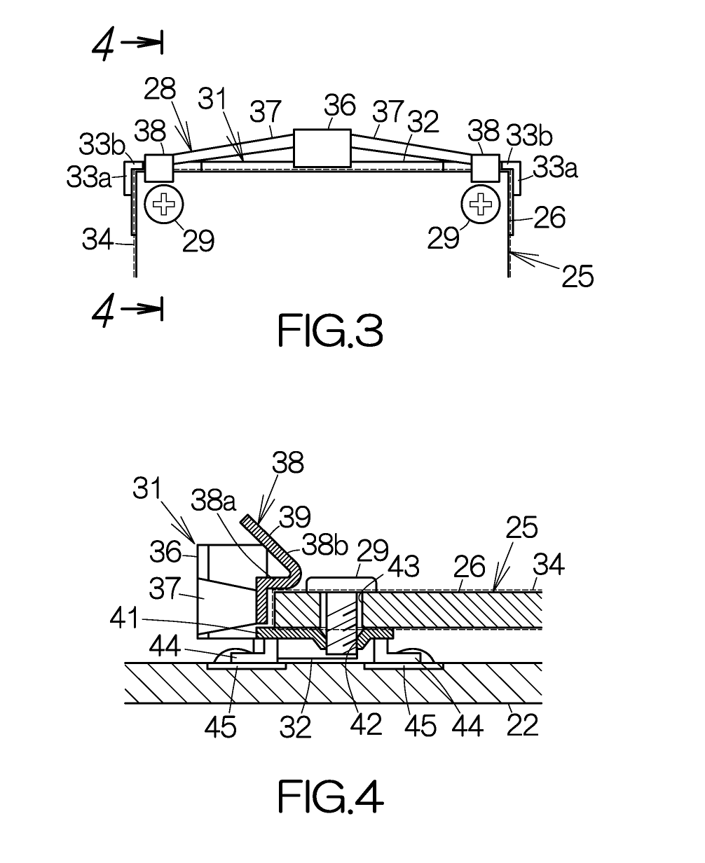

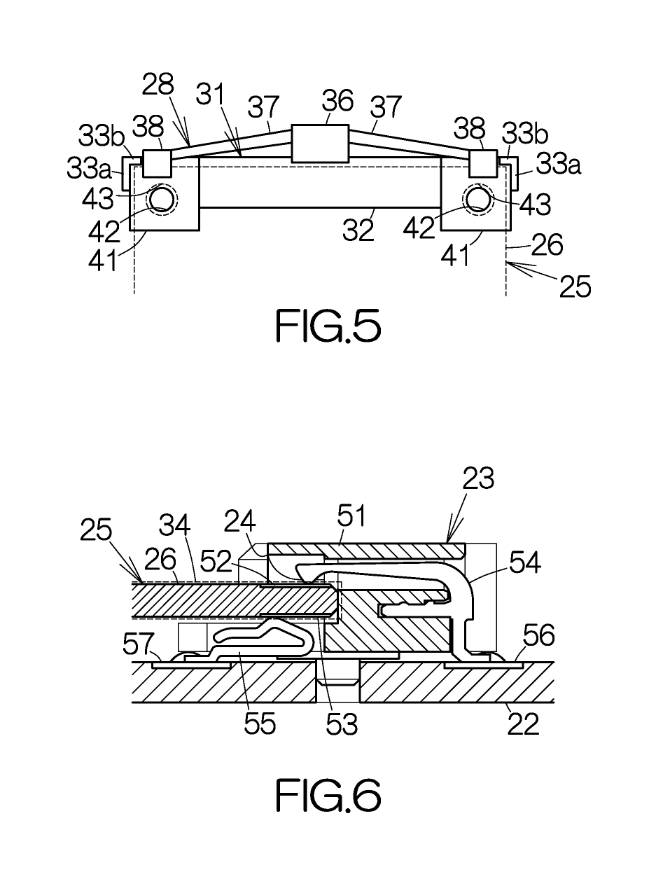

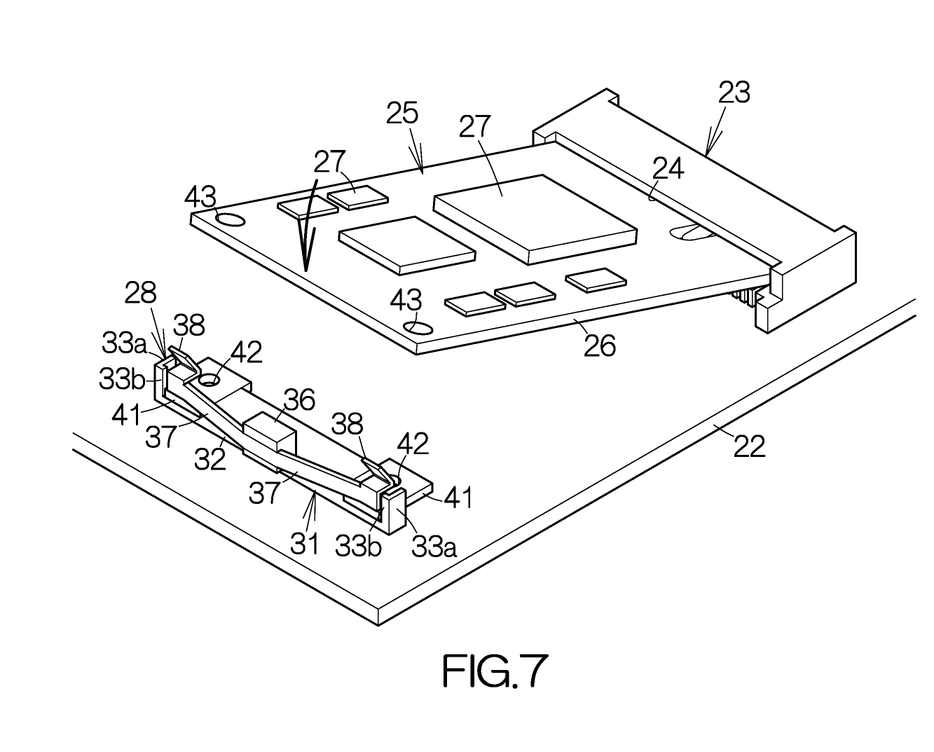

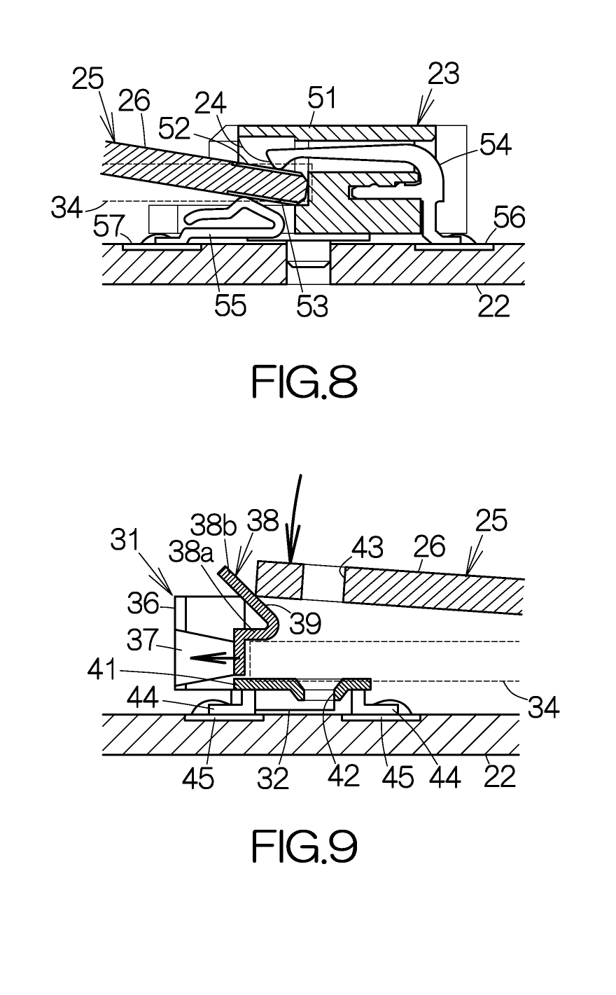

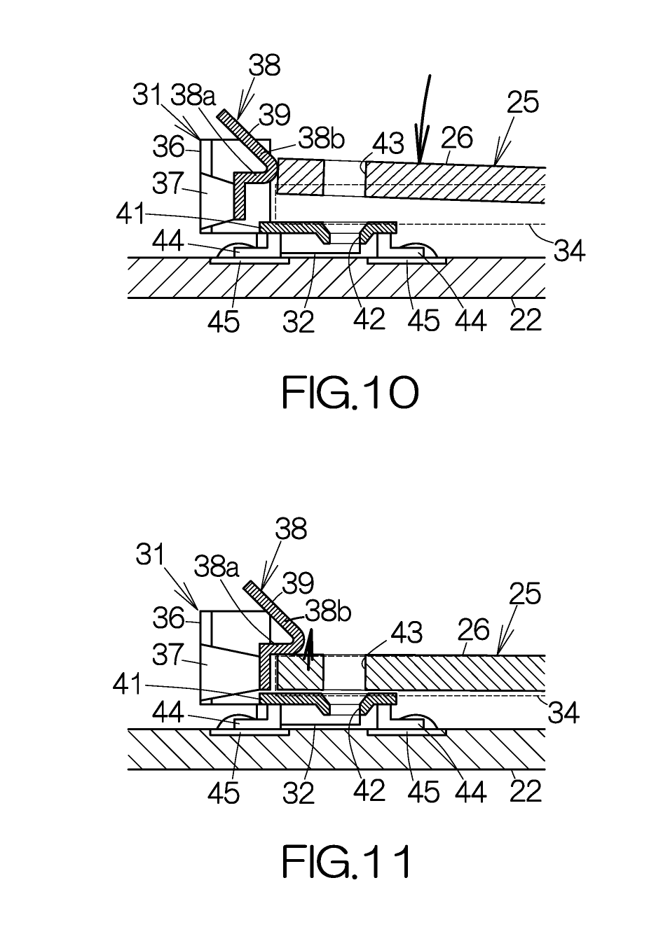

As depicted in FIG. 4, when the engagement members 38 are set at the reference positions, the aforementioned space 34 in the shape of a rectangular parallelepiped is placed in a space between the base body 32 and the engagement members 38. The individual engagement member 38 defines a horizontal piece 38a extending in the horizontal direction in parallel with the surface of the base body 32. The horizontal piece 38a protrudes toward the socket 23 from the top of the elastic member 37 at the outer end of the elastic member 37. A tip end piece 38b is connected to the outer end of the horizontal piece 38a. The tip end piece 38b extend upward in an inclined attitude from the horizontal piece 38a. The module substrate 26 is located in a space between the base body 32 and the horizontal pieces 38a of the engagement pieces 38. The individual tip end piece 38b defines an inclined surface 39. The inclined surface 39 gets farther from the space 34 as the position gets farther inward in the horizontal direction from the contour of the module substrate 26.

Referring also to FIG. 5, support plates 41 are attached to the base body 32 at positions adjacent to the opposite ends of the base body 32. The support plates 41 extend in the horizontal direction in parallel with the surface of the printed wiring board 22. The support plates 41 are made of a metallic plate, for example. A screw bore 42 is formed in the individual support plate 41 for receiving the insertion of the screw 29. The longitudinal or rotation axes of the screw bores 42 are set in the perpendicular direction perpendicular to the surface of the printed wiring board 22. The screw bores 42 are connected to through holes 43 formed in the module substrate 26, respectively. The positions of the through holes 43 are determined on the module substrate 26 in accordance with the standards. The screws 29 are screwed into the screw bores 42 through the through holes 43, respectively. A pair of terminals 44 is attached to the base body 32, for example. The terminals 44 are made of a metal material, for example. The terminals 44 are soldered on pads 45 formed on the surface of the printed wiring board 22, respectively. The pads 45 are made of a metal material, for example. In this manner, the fixation mechanism 28 is rigidly fixed on the surface of the printed wiring board 22.

The fixation mechanism 28 allows integral formation of the base body 32, the wall members 33a, the auxiliary wall members 33b and the block piece 36 into the base 31 based on molding process using a resin material. A die is prepared for the molding process. The support plates 41 are beforehand set in the cavity of the die at predetermined positions. The support plates 41 are thus embedded in the base 31 through the molding process. The support plates 41 are in this manner firmly immobilized to the base 31. The elastic members 37 and the engagement members 38 may thereafter be attached to the block piece 36. It should be noted that the terminals 44 may be formed integral with the support plates 41, respectively, for example.

As depicted in FIG. 6, the socket 23 includes a socket body 51 in the shape of a rectangular parallelepiped, for example. The socket body 51 is made of a resin material, for example. Molding process may be employed in this case. The aforementioned slot 24 is formed in the front of the socket body 51. The first end of the module substrate 26 is received in the socket body 51 through the slot 24. Front-side electrically-conductive terminals 52 are formed on the front surface of the module substrate 26 along the outer periphery of the module substrate 26 at the short side of the module substrate 26. Likewise, back-side electrically-conductive terminals 53 are formed on the back surface of the module substrate 26 along the outer periphery of the module substrate 26 at the short side of the module substrate 26. The front-side and back-side electrically-conductive terminals 52, 53 are connected to the aforementioned electronic components 27.

The socket 23 includes first electrically-conductive terminals 54 rigidly fixed to the socket body 51. Second electrically-conductive terminals 55 are rigidly fixed to the socket body 51. The individual first electrically-conductive terminal 54 exhibits an elastic force to urge one end of the first electrically-conductive terminal 54 against the corresponding front-side electrically-conductive terminal 52. The other end of the individual first electrically-conductive terminal 54 is soldered to an electrically-conductive pad on the printed wiring board 22. The individual second electrically-conductive terminal 55 exhibits an elastic force to urge one end of the second electrically-conductive terminal 55 against the back-side electrically-conductive terminal 53. The other end of the individual second electrically-conductive terminal 55 is soldered to an electrically-conductive pad 57 on the printed wiring board 22. In this manner, the expansion card 25 is electrically connected to the printed wiring board 22.

As is apparent from FIG. 6, the contact point of the first electrically-conductive terminals 54 against the module substrate 26 is located closer to the outer periphery of the module substrate 26 than the contact point of the second electrically-conductive terminals 55 against the module substrate 26 is. Accordingly, the elastic forces of the first and second electrically-conductive terminals 54, 55 always act on the module substrate 26 so as to lift the second end of the module substrate 26 away from the surface of the printed wiring board 22.

Next, description will be made on a method of making the motherboard 21. The socket 23 and the fixation mechanism 28 have beforehand been fixed on the surface of the printed wiring board 22. As depicted in FIG. 7, the first end of the module substrate 26 of the expansion card 25 is inserted into the slot 24 of the socket 23. The module substrate 26 is kept in an inclined attitude during the insertion. The first end of the module substrate 26 is held against an inner wall surface of the socket body 51, as depicted in FIG. 8. When and operator pushes the second end of the expansion card 25 toward the surface of the printed wiring board 22, the module substrate 26 pivotally moves around the first end. The pivotal movement of the module substrate 26 generates elastic deformation of the first and second electrically-conductive terminals 54, 55 since the first and second electrically-conductive terminals 54, 55 keep contacting with the module substrate 26. The elastic deformation causes accumulation of a resilient force in the first and second electrically-conductive terminals 54, 55.

As depicted in FIG. 9, the engagement members 38 are set at the reference positions. The second end of the module substrate 26 is received on the inclined surfaces 39 of the tip end pieces 38b. As the operator keep pushing the second end of the module substrate 26 toward the surface of the printed wiring board 22, the individual inclined surface 39 receives the application of the downward force from the second end of the module substrate 26. Since the elastic members 37 are made of a leaf spring in the perpendicular attitude perpendicular to the surface of the module substrate 26, the downward force causes movement of the engagement members 38 in the horizontal direction along the surface of the printed wiring board 22. As a result, the engagement members 38 move backward from the reference positions to withdraw the horizontal pieces 38a from the space right on the module substrate 26, as depicted in FIG. 10. The engagement members 38 are set at withdrawing positions, respectively. An elastic force is accumulated in the elastic members 37 during the backward movement of the engagement members 38 from the reference positions to the withdrawing positions. In this case, the module substrate 26 is positioned inside the wall members 33a and the auxiliary wall members 33b along the wall members 33a and the auxiliary wall members 33b.

When the module substrate 26 is completely contained in the space 34, the module substrate 26 takes a horizontal attitude in parallel with the surface of the printed wiring board 22. Since the engagement members 38 fall off the inclined surfaces 39, namely the tip end pieces 38b, respectively, the engagement members 38 move from the withdrawing positions to the reference positions. In this manner, the engagement members 38 enter the space right on the module substrate 26, as depicted in FIG. 11. The module substrate 26 keeps subjected to the aforementioned force to lift the second end of the module substrate 26, the second end of the module substrate 26 is received on the horizontal pieces 38a of the engagement members 38. The module substrate 26 is thus reliably prevented from moving out of the space 34. In this state, the quality of the motherboard 21 is examined. Electrical conduction is established in the motherboard 21. If the motherboard 21 is determined satisfactory through the examination, the screws 29 are screwed into the screw bores 42 of the support plates 41. The screws 29 serve to reliably establish a rigid fixation of the expansion card 25 to the printed wiring board 22. The rigid fixation cannot be released without a tool.

If the examination reveals an unsatisfactory condition in the motherboard 21, the expansion card 25 is detached from the motherboard 21. The operator moves the engagement members 38 from the reference positions to the withdrawing positions so as to detach the expansion card 25. When the engagement members 38 are completely driven out of the space right on the module substrate 26, the module substrate 26 is released from the engagement with the engagement members 38. The resilient force of the first and second electrically-conductive terminals 54, 55 causes the upward movement of the second end of the module substrate 26. The second end of the module substrate 26 pivotally moves upward around the first end of the module substrate 26. The attitude of the module substrate 26 changes from the horizontal attitude to the inclined attitude. The module substrate 26 can be detached from the printed wiring board 22 in a relatively facilitated manner.

One end of the module substrate 26 is supported at the socket 23 when the expansion card 25 is set on the printed wiring board 22 of the motherboard 21. The other end of the module substrate 26 is supported at the fixation mechanism 28. Specifically, the engagement members 38 serve to hold the module substrate 26 on the base 31. The engagement members 38 are configured to move in the horizontal direction between the reference positions and the withdrawing positions, respectively. It is easy to realize attachment and detachment of the module substrate 26, namely the expansion card 25. The expansion card 25 can provisionally be attached to the printed wiring board 22 for the examination of the quality of the motherboard 21. If the motherboard 21 is determined unsatisfactory, the expansion card 25 can be detached from the printed wiring board 22 in a relatively facilitated manner.

When the motherboard 21 is determined satisfactory, the screws 29 are utilized to establish a rigid fixation of the module substrate 26 to the support plates 41, namely the fixation mechanism 28, through the through holes 43 of the module substrate 26. The detachment of the module substrate 26, namely the expansion card 25, cannot be realized without a troublesome operation of an operator. In addition, the wall members 33a and the auxiliary wall members 33b are formed integral with the base body 32. The wall members 33a face to each other. Guiding of the module substrate 26 along the wall members 33a for the attachment of the module substrate 26 to the fixation mechanism 28 enables prevention of a shift in the position of the module substrate 26 in the lateral direction defined along the short side of the module substrate 26. Likewise, the auxiliary wall members 33b serve to prevent a shift in the position of the module substrate 26 in the longitudinal direction defined along the long side of the module substrate 26.

It should be noted that the socket 23 and the fixation mechanism 28 may be formed integral with each other in the motherboard 21. In this case, the socket body 51 of the socket 23 and the base 31 of the fixation mechanism 28 may be coupled with each other via a coupling member, for example. An integral formation of the socket 23 and the fixation mechanism 28 reliably prevents a shift in the relative positions of the socket 23 and the fixation mechanism 28.

All examples and conditional language recited herein are intended for pedagogical purposes to aid the reader in understanding the invention and the concept contributed by the inventor to furthering the art, and are to be construed as being without limitation to such specifically recited examples and conditions, nor does the organization of such examples in the specification relate to a showing of the superiority and inferiority of the invention. Although the embodiment of the present inventions have been described in detail, it should be understood that the various changes, substitutions, and alterations could be made hereto without departing from the spirit and scope of the invention.

What is claimed is:

1. A printed circuit board unit comprising:
a printed wiring board;
a socket mounted on a surface of the printed wiring board;
a fixation member mounted on the surface of the printed wiring board at a position spaced from the socket by a predetermined distance;
a screw bore defined in the fixation member, the screw bore receiving insertion of a screw in a perpendicular direction perpendicular to the surface of the printed wiring board;
an engagement member configured to move in a horizontal direction along the surface of the printed wiring board between a reference position and a withdrawing position, the engagement member set at the reference position so that a predetermined space is defined between the engagement member and the fixation member, the engagement member withdrawing from the reference position to the withdrawing position so as to get out of the predetermined space; and
an elastic member configured to exhibit an elastic force urging the engagement member toward the reference position.

2. The printed circuit board unit according to claim 1, wherein an inclined surface is defined on the engagement member, the inclined surface getting farther from the space as a position gets farther from the reference position toward the withdrawing position in the horizontal direction.

3. The printed circuit board unit according to claim 1, further comprising a pair of wall members defined on the fixation member, the wall members extending along the space, the wall members opposed to each other with the space interposed therebetween.

4. The printed circuit board unit according to claim 1, further comprising an auxiliary wall member defined on the fixation member, the auxiliary wall member extending along the space, the auxiliary wall members opposed to the socket with the space interposed therebetween.

5. An electronic apparatus comprising:
an enclosure;
a printed wiring board enclosed in the enclosure;
a socket mounted on a surface of the printed wiring board;
a fixation member mounted on the surface of the printed wiring board at a position spaced from the socket by a predetermined distance;
a module substrate having one end supported on the socket and an other end received on the fixation member, the module substrate defining a through hole at a position adjacent to the other end;
a screw bore defined in the fixation member, the screw bore connected to the through hole of the module substrate;
a screw screwed into the screw bore through the through hole of the module substrate;
an engagement member configured to move in a horizontal direction along the surface of the printed wiring board between a reference position and a withdrawing position, the engagement member set at the reference position so that the module substrate is interposed between the engagement member and the fixation member, the engagement member withdrawing from the reference position to the withdrawing position so as to get out of a contour of the module substrate; and
an elastic member configured to exhibit an elastic force urging the engagement member toward the reference position.

6. The electronic apparatus according to claim 5, wherein an inclined surface is defined on the engagement member, the inclined surface getting farther from the module substrate as a position gets farther from a contour of the printed wiring board in the horizontal direction.

7. The electronic apparatus according to claim 5, further comprising a pair of wall members defined on the fixation member, the wall members extending along an outer periphery of the module substrate, the wall members opposed to each other with the module substrate interposed therebetween.

8. The electronic apparatus according to claim 5, further comprising an auxiliary wall member defined on the fixation member, the auxiliary wall member extending along an outer periphery of the module substrate, the auxiliary wall member opposed to the socket with the module substrate interposed therebetween.

9. A printed circuit board unit comprising:
a printed wiring board;
a socket mounted on a surface of the printed wiring board, the socket supporting one end of a module substrate;
a fixation member mounted on the surface of the printed wiring board at a position spaced from the socket, the fixation member supporting an other end of the module substrate;
a screw bore formed in the fixation member, the screw bore receiving insertion of a screw configured to fix the module substrate to the fixation member; and
a support member formed in the fixation member, the support member configured to move between a first position at which the support member supports the other end of the module substrate and a second position at which the support member gets distanced from the other end of the module substrate, the support member being urged toward the socket by an elastic member.
